(19) United States
(12) Patent Application Publication
(10) Pub. No.: US 2013/0187700 A1
(43) Pub. Date: Jul. 25, 2013

(54) ENERGY REUSE CIRCUIT

(71) Applicant: Yu-Chi Huang, Hsinchu (TW)

(72) Inventor: Yu-Chi Huang, Hsinchu (TW)

(21) Appl. No.: 13/541,832

(22) Filed: Jul. 5, 2012

(30) Foreign Application Priority Data
Jan. 20, 2012 (TW) 101102484

(51) Int. Cl. H03K 17/00

(52) U.S. Cl. 327/365

(57) ABSTRACT

The present invention provides an energy reuse circuit. The energy reuse circuit is connected among a plurality of converters at a releasing side or an absorbing side, and includes an energy absorbing portion, an energy releasing portion and an energy exchange portion, wherein the energy exchange portion is connected to the energy absorbing portion and the energy releasing portion, so as to make the energy absorbing portion and the energy releasing portion exchange potential energy in sequence and thus complete energy reuse.

### CROSS-REFERENCE TO RELATED APPLICATIONS

The present application is based on, and claims priority from, Taiwan Application Serial Number 101102484, filed on Jan. 20, 2012, the disclosure of which is hereby incorporated by reference herein in its entirety.

### BACKGROUND OF THE INVENTION

1. Field of the Invention

The present invention relates to energy reuse circuits, and, more particularly, to an energy reuse circuit using switching of switches to achieve soft switching.

2. Description of Related Art

A switching device is used for a power supply circuit to switch power between inductor and capacitor, and thus to output different voltages. To meet differing requirements, boost, buck, buck-boost, AC/DC or DC/AC are available.

It is important for the switching device to have small size, high efficiency and high reliability. However, energy may be lost during switching, and thus produce a lot of heat which needs to be overcome to promote the efficiency, reliability and life time of the switching device or whole system. Efficient heat-dissipating devices usually need a large area for dissipating heat, which goes against the miniature design trend of commercial electronic products.

To make a trade-off between reliability, size and efficiency, soft switching technologies, such as ZVS (zero voltage switching), ZCS (zero current switching), ZVT (zero voltage transition) and ZCT (zero current transition), have been developed. However, ZVS and ZCS need external auxiliary circuits serially connected to primary circuits, and ZVT and ZCT need external auxiliary circuit connected to primary circuits in shunt. Therefore, for the complicated primary circuits, the auxiliary circuits may have many components and complex designs, so as to degrade the efficiency, reliability and life time, as well as increase the size of electronic products.

U.S. Pat. No. 7,916,505 discloses an auxiliary circuit for reducing energy lost during switching of a primary circuit. However, in such design, the auxiliary circuit 220 is complicated circuits which have a passive clamping circuit 308 for absorbing energy and a step-down circuit 318 for recovering energy. In the case of multiple primary circuits, many auxiliary circuits are needed and thus more design complexity can not be avoided.

### SUMMARY OF THE INVENTION

In order to overcome the drawbacks in the prior art, the present invention provides a soft switching technology for balancing reliability, size and efficiency.

The present invention provides an energy reuse circuit connected to releasing sides or absorbing sides of a plurality of converters. The energy reuse circuit includes an energy absorbing portion; an energy releasing portion; and an energy exchange portion connected to the energy absorbing portion and the energy releasing portion and configured to allow the energy absorbing portion and the energy releasing portion to exchange potential energy in sequence, thereby completing energy reuse.

In comparison with the prior art, the energy absorbing portion and the energy releasing portion exchange potential energy in sequence, so as to complete zero-voltage and zero-current switching, and the present invention uses fewer components with lower cost for storing the energy lost in switching. Hence, the reliability, efficiency and life time of the system are improved and the size is reduced by using the energy reuse circuit of the present invention.

### BRIEF DESCRIPTION OF THE DRAWINGS

FIG. 1A is a schematic view which shows the functional block diagram of the energy reuse circuit according to the present invention;

FIG. 1B is a schematic view which shows the configuration of the energy reuse circuit shown in FIG. 1A;

FIG. 2A is a schematic view which shows a variation of the configuration shown in FIG. 1B;

FIG. 2B and FIG. 2C are schematic views that each shows the circuits according to the configuration of FIG. 2A;

FIG. 3A is a schematic view which shows a variation of the configuration shown in FIG. 1B;

FIG. 3B is a schematic view which shows a circuit of the configuration shown in 3A;

FIG. 4A is a schematic view which shows a variation of the configuration shown in FIG. 1B;

FIG. 4B and FIG. 4C are schematic views which show a circuit of the configuration shown in 4A;

FIG. 5A is a schematic view which shows a circuit according to FIG. 2B;

FIG. 5B is a plot that shows the time sequence of FIG. 5A;

FIG. 5C is a schematic view which shows a practical application of FIG. 5A;

FIG. 6A is a schematic view which shows a variation of the configuration shown in FIG. 1B;

FIG. 6B, FIG. 6C and FIG. 6D are schematic views that each shows a circuit of the configuration shown in 6A;

FIG. 7A is a schematic view which shows a variation of the configuration shown in FIG. 1B;

FIG. 7B and FIG. 7C are schematic views that each shows a circuit of the configuration shown in 7A;

FIG. 8A is a schematic view which shows a variation of the configuration shown in FIG. 1B;

FIGS. 8B, 8C and 8D are schematic views that each shows a circuit of the configuration shown in 8A;

FIG. 9A is a schematic view which shows a variation of the configuration shown in FIG. 1B;

FIG. 9B and FIG. 9C are schematic views that each shows a circuit of the configuration shown in 9A; and

FIG. 10 is a schematic view which shows a circuit of the configuration shown in FIG. 1B.

### DETAILED DESCRIPTION OF THE PREFERRED EMBODIMENTS

A detailed description of the present invention is illustrated by the following specific examples. Persons skilled in the art can conceive other advantages and effects of the present invention based on the disclosure contained in the specification of the present invention.

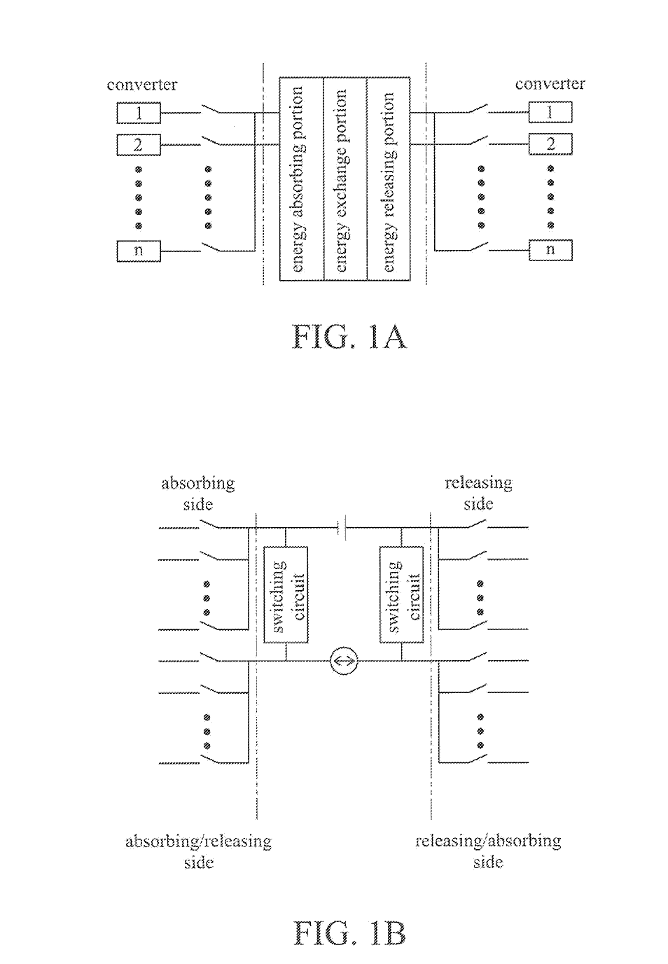

FIG. 1A shows the functional block diagram of the energy reuse circuit of the present invention.

As shown in FIG. 1A, the energy reuse circuit is used in a plurality of converters 1−n, and the converters 1−n may be disposed at a releasing side or an absorbing side. The energy reuse circuit includes an energy absorbing portion, an energy releasing portion and an energy exchange portion. The converters 1−n may be heterogeneous or homogeneous, and disposed at the absorbing side or the releasing side, respectively. For example, heterogeneous converters are disposed at an absorbing side (relatively lower voltage) and heterogeneous converters are disposed at a releasing side (relatively higher voltage), such that the energy exchange portion is configured to allow the energy absorbing portion and the energy releasing portion to exchange potential energy, so as to complete energy reuse.

FIG. 1B shows the circuit according to the configuration shown in FIG. 1A.

As shown in FIG. 1B, the energy absorbing portion, the energy releasing portion and the energy exchange portion are composed of a switching circuit, a voltage source component and a current source component. The energy exchange portion is a switching circuit. The energy absorbing portion and the energy releasing portion are current source components or voltage source components. The two ends of the switching circuit are respectively connected to the current source component and the voltage source component. The current source component or the voltage source component may be connected to the releasing side or the absorbing side.

In this embodiment, the switching circuit may include a switch, an open circuit or a short circuit. The switch may be a semiconductor switch such as transistor, diode or thyristor, or an electronic switch such as a relay. The current source component may be a unidirectional or bidirectional current source component such as an inductor for releasing current. The voltage source component may be a polarized voltage source component such as a capacitor for releasing current.

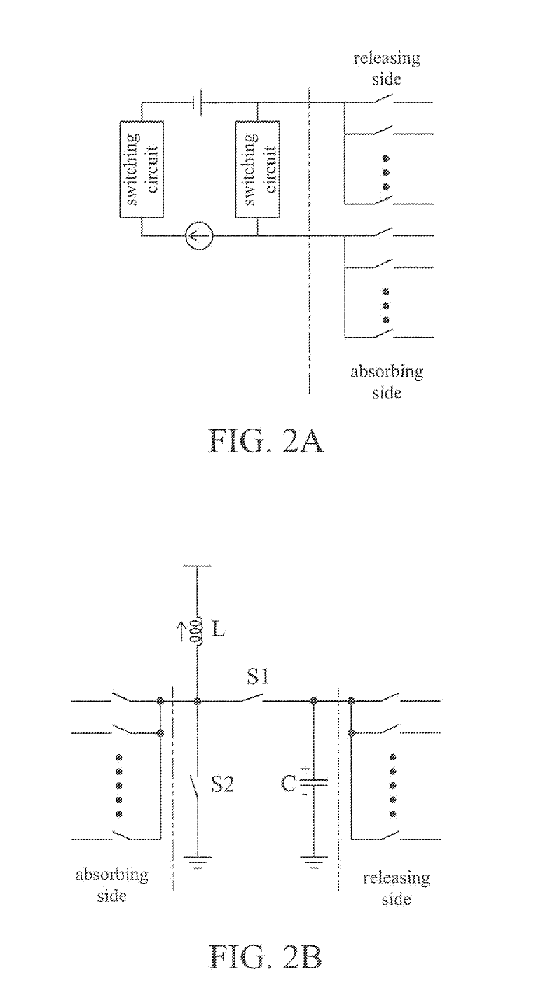

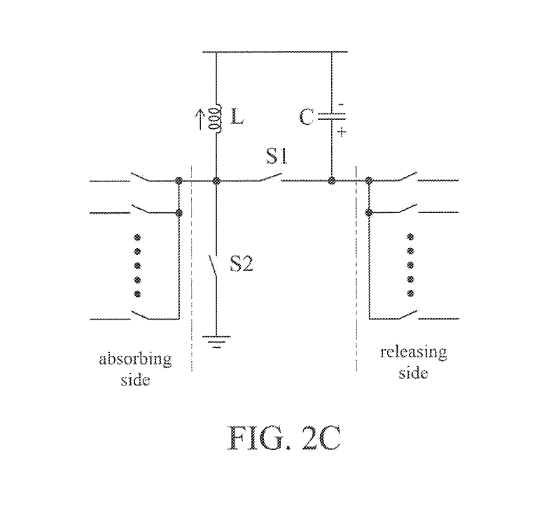

The following description illustrates the variations of the configuration shown in FIG. 1B. FIGS. 2A, 3A, 4A, 6A, 7A, 8A, 9A and 10 illustrate the variations of the configuration shown in FIG. 1B.

As shown in FIG. 2A, the two ends of each of the two switching circuits are respectively connected to the voltage source component and the current source component, and one end of the voltage source component or the current source component is connected to the releasing side or the absorbing side.

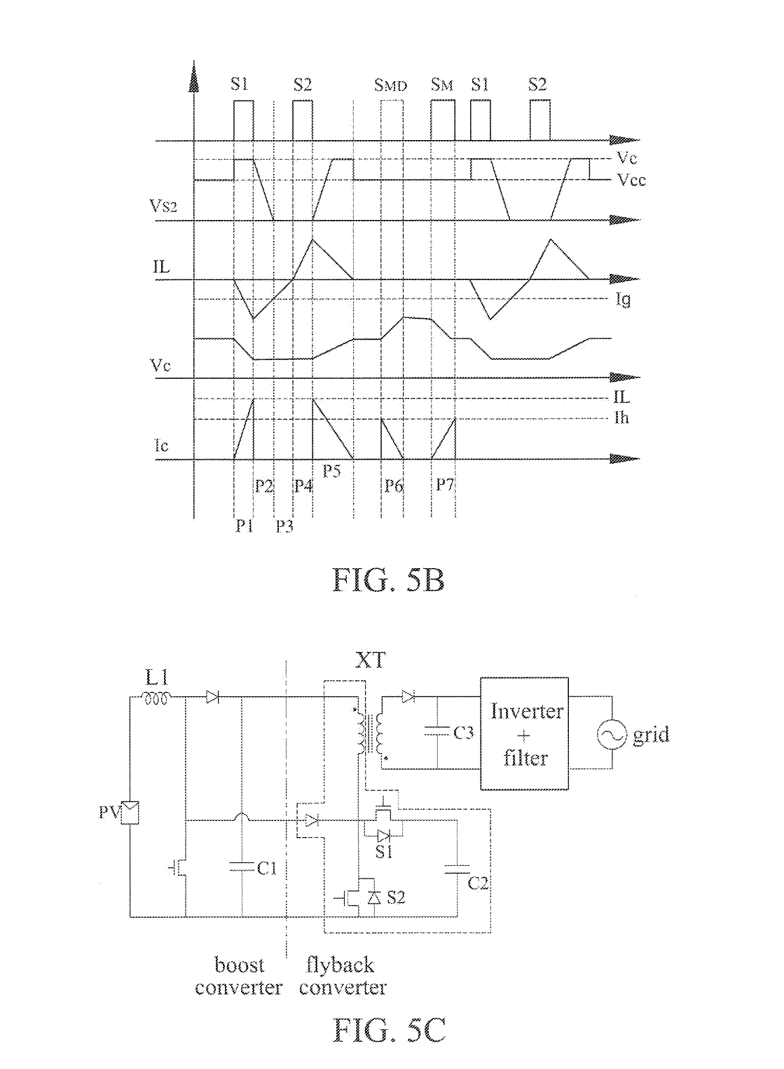

The circuit shown in FIG. 2A may be formed in the configuration of FIG. 2B or FIG. 5A, wherein an inductor L is a current source component having one end connected to an input power source end and having the other end connected to a switch S1, a switch S2 and an absorbing side. The switch S1 may be a transistor or a diode having two ends respectively connected to the absorbing side and the releasing side. The switch S2 may a transistor or a diode having one end connected to the absorbing side, the switch S1 and the inductor L, and having the other end connected to the ground. The capacitor C is a voltage source component having one end connected to the switch S1 and the releasing side, and having the other end connected to the ground.

Thus, the switches S1 and S2 alternately perform switching, such that the inductor L and the capacitor C perform charging and discharging in sequence, i.e. exchanging potential energy, so as to complete energy reuse and zero voltage switching at the absorbing side.

In the embodiment shown in FIG. 5A, the transistor Sm and the diode Smd connected in shunt may be disposed at the releasing side to alternatively perform switching after the zero voltage switching at the absorbing side, and to charge the capacitor C by using the leakage current at the releasing side, such that zero voltage switching at the releasing side is completed. At the absorbing side, multiple transistors or diodes connected in shunt may be disposed, and diodes are exemplified in FIG. 5A.

For furthering illustrating the circuit shown in FIG. 5A, FIG. 5B shows the time sequence of the circuit.

In FIG. 5B, Ig indicates the total current through the absorbing side; Ih indicates the total current at the releasing side; Va indicates the voltage at the connection between the inductor L, the absorbing side and the switch S1; Vc indicates the voltage at the connection between the switch S1, the releasing side and the capacitor C; and IL indicates the current through the inductor L.

In phase P1, the switch S1 is turned on (S1=on) to force Va=Vc, the capacitor C discharges into the inductor L through the switch S1, and after IL of the inductor L is larger than Ig, the switch S1 is turned off (S1=off). Then, phase P2 is performed. In phase P2, the current IL of the inductor L would absorb Ig, and Va is thus gradually decreased to 0 V. Then, phase P3 is performed.

In phase P3, the current IL of the inductor L cannot be zero instantly, and thus the inductor L would absorb Ig completely. After absorbing Ig, IL would discharge to the input power source end by passing through the diode of switch S2 (may be a body diode of the switch 2), so as to decrease Va to zero. In other words, in phase P3, zero voltage switching of all primary converters connected via the diode to the absorbing side (relatively lower voltage) is completed. Accordingly, the energy reuse circuit of the present invention provides a switching environment at zero voltage in phases P1-P3, and further completes zero voltage switching of the primary converters connected with the energy reuse circuit.

In phase P4, the switch S2 is turned on (S2=on) to make the input power source end discharge into the inductor L. Then, phase P5 is performed. In phase P5, the switch S2 is turned off (S2=off), and the diode of the switch S1 (may be a body diode of the switch 1) is turned on, so as to make the current IL on the inductor L charge the capacitor C. Thus, in phases P1-P5, zero voltage switching of all converters connected to the absorbing side is completed.

In phase P6, the diode Smd is turned on (Smd=on) to make the leakage current at the releasing side (relatively higher voltage) charge the capacitor C. In phase P7, the transistor Sm is turned on (Sm=on) to make the capacitor C charge all switches of the primary circuit to high voltage, so as to complete zero voltage switching at relatively higher voltage.

Hence, alternate switching is performed by the many switches, such that the inductor L as the current source component and the capacitor C as the voltage source component can charge and discharge into each other. Accordingly, the potential energy exchange can be performed by the configuration with fewer component and lower cost, and also switching of zero-voltage/zero-current and energy reuse are achieved.

In addition, the configuration shown in FIG. 5A may be used between the boost converter and the flyback converter shown in FIG. 5C. In FIG. 5C, the switch S2 may be merged with the primary switch of the flyback converter because the inductor L can be replaced by parasitic inductor of the transformer (XT).

The configuration shown in FIG. 2A may be varied as that in FIG. 2C. The configuration of FIG. 2C differs from the configuration of FIG. 2B in that the capacitor C as the voltage source component is selectively connected to the inductor L as the current source component in shunt.

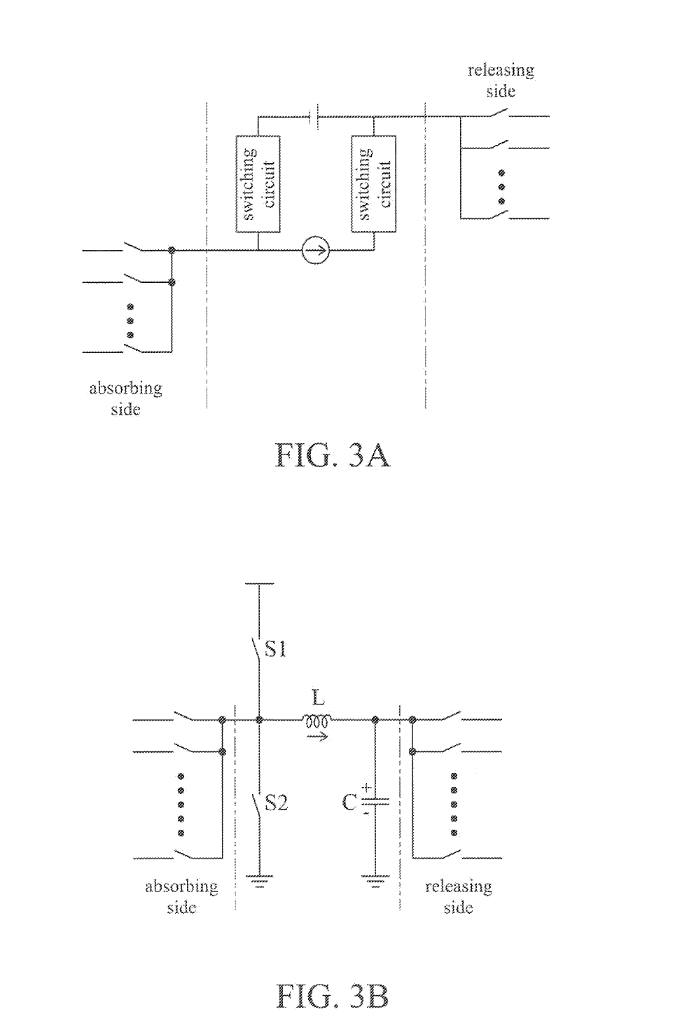

The following description illustrates the variations of the configuration shown in FIG. 1B. FIGS. 3A, 4A, 6A, 7A, 8A, 9A and 10 illustrate the variations of the configuration shown in FIG. 1B.

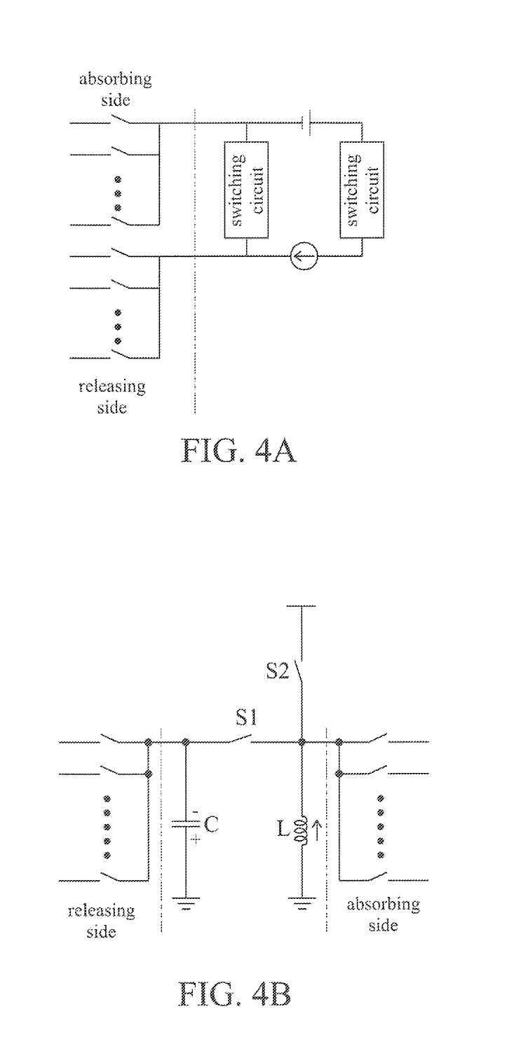

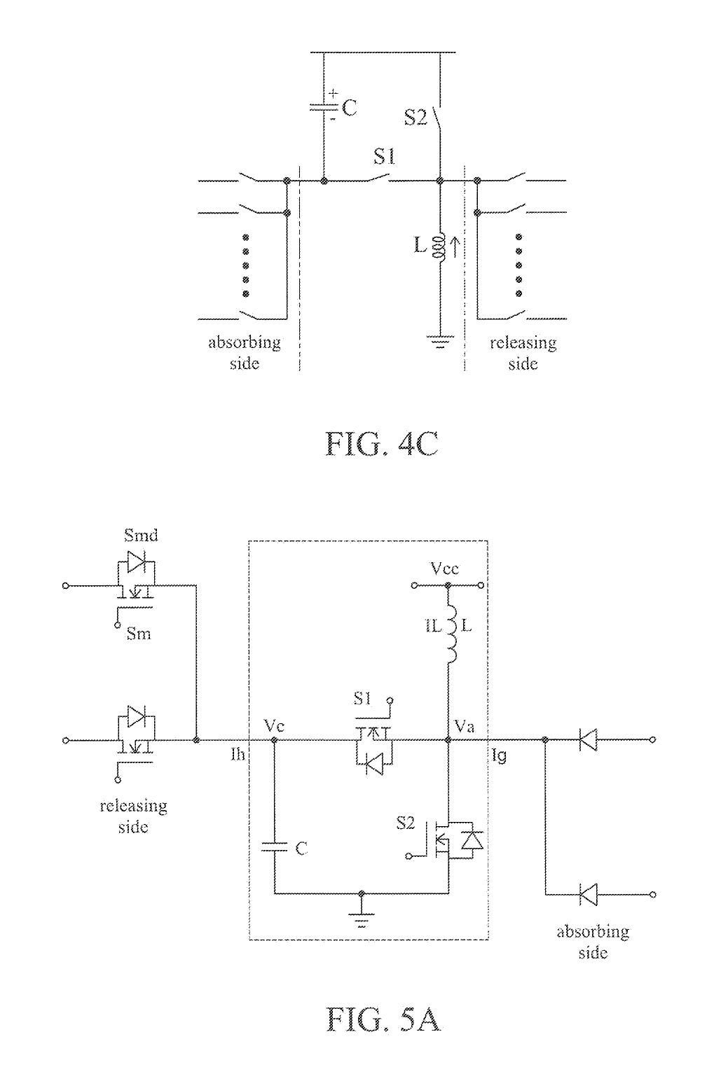

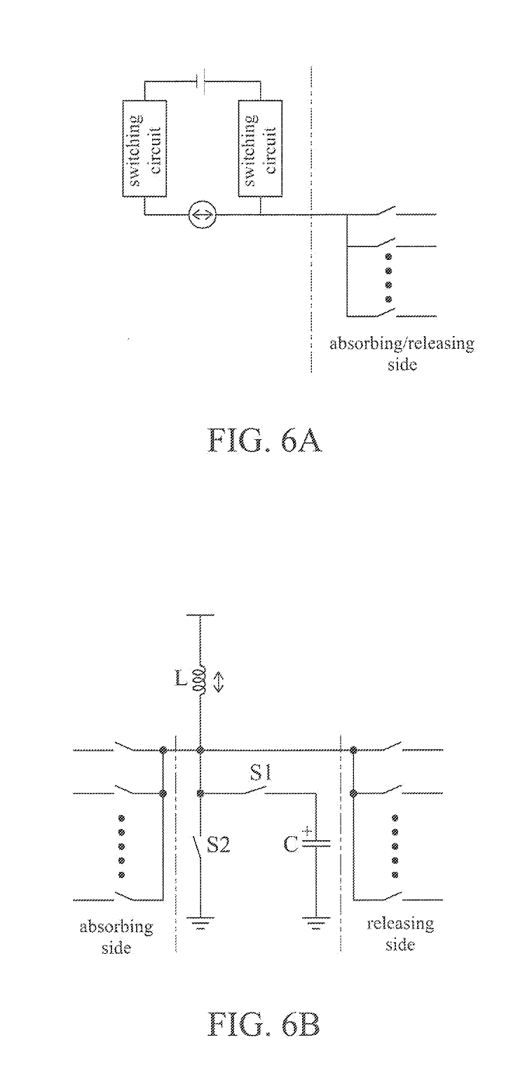

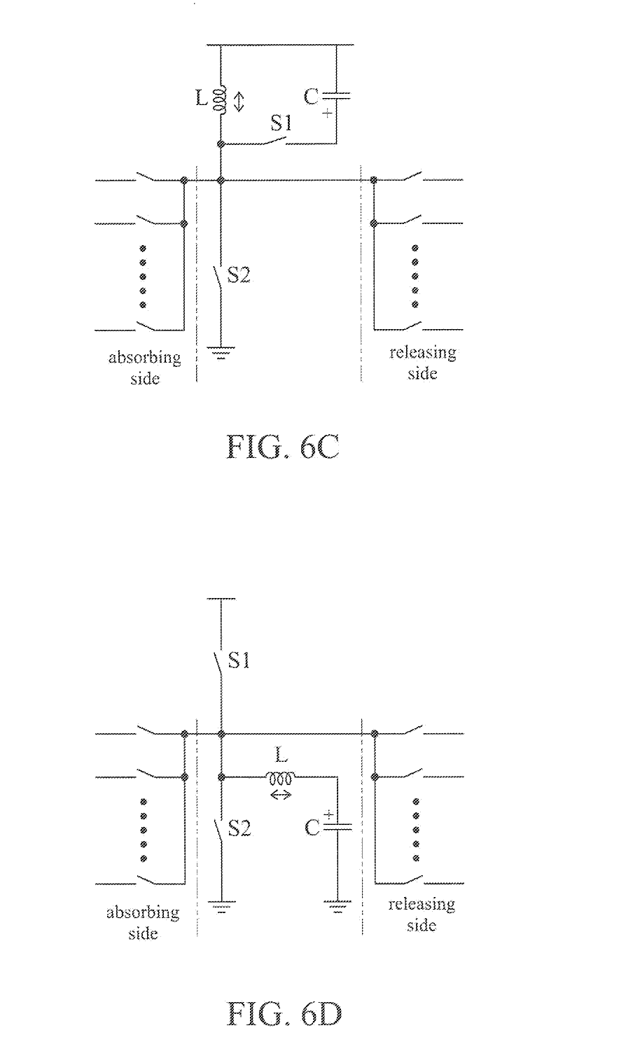

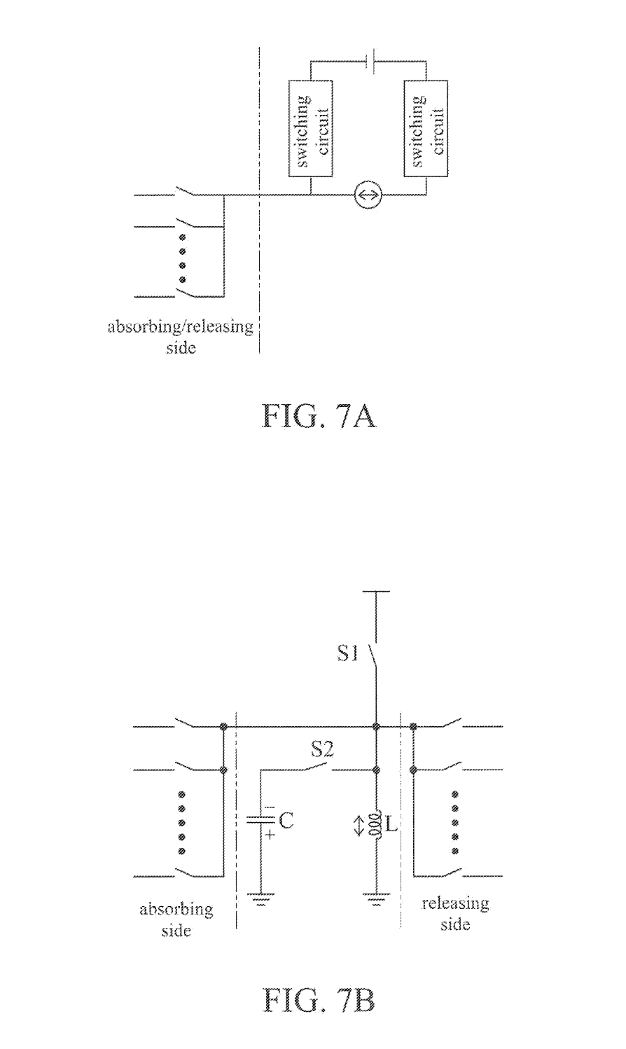

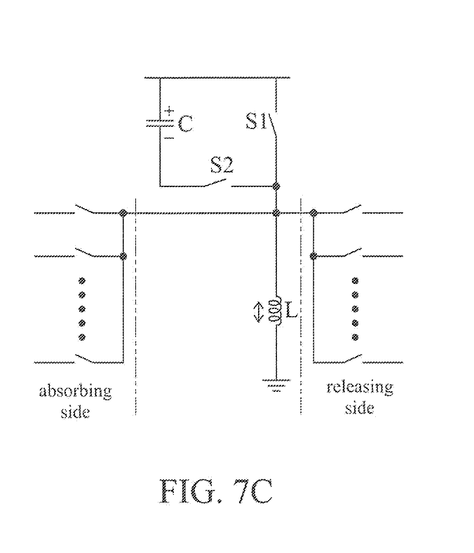

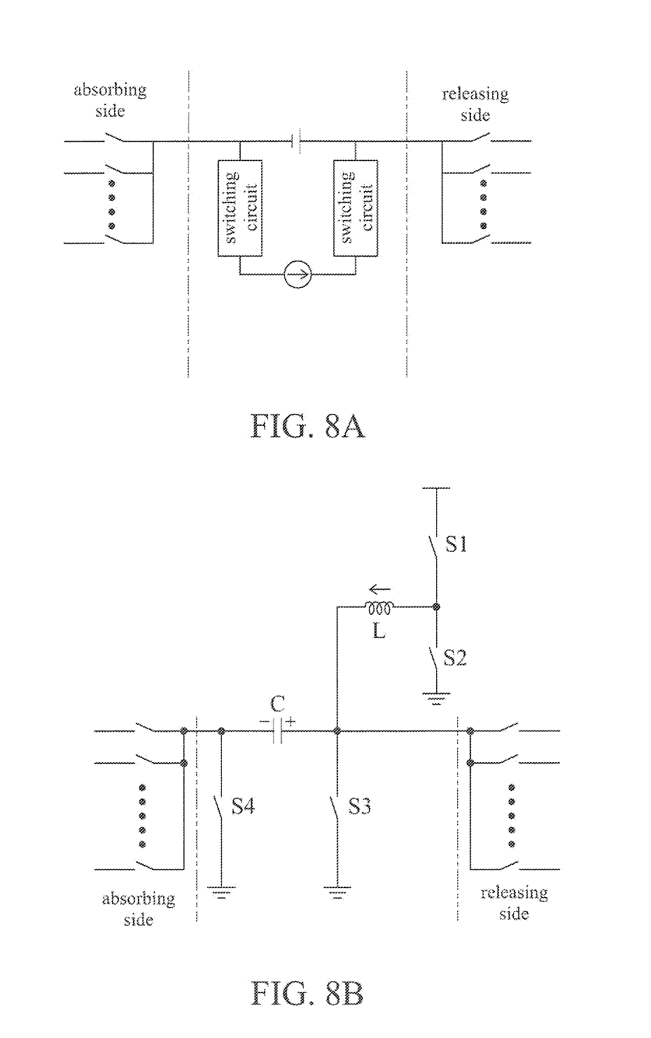

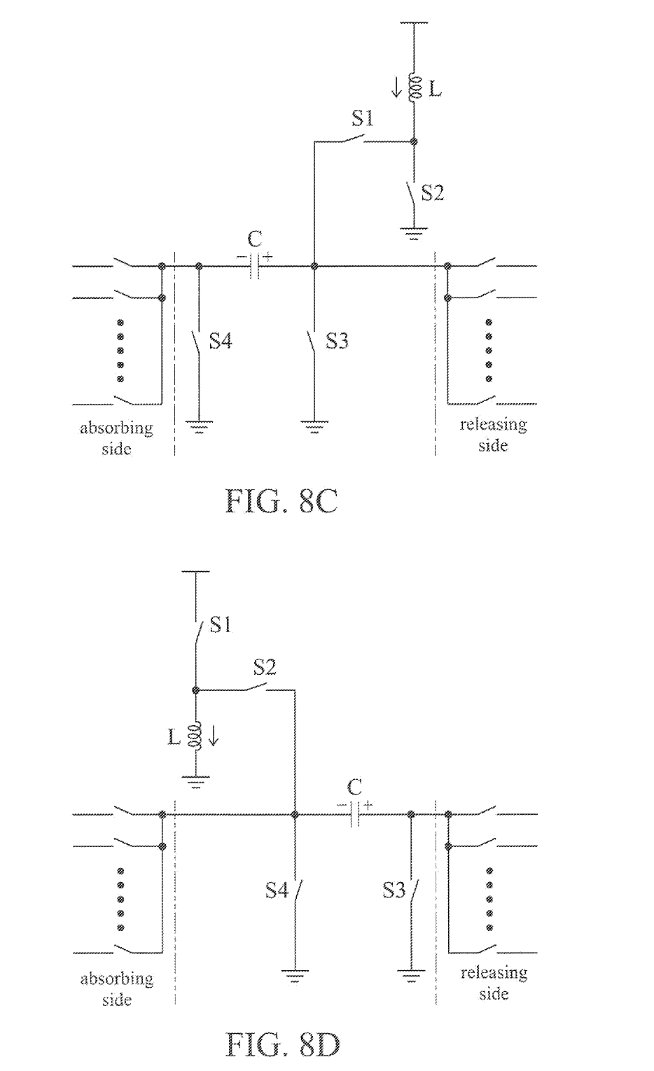

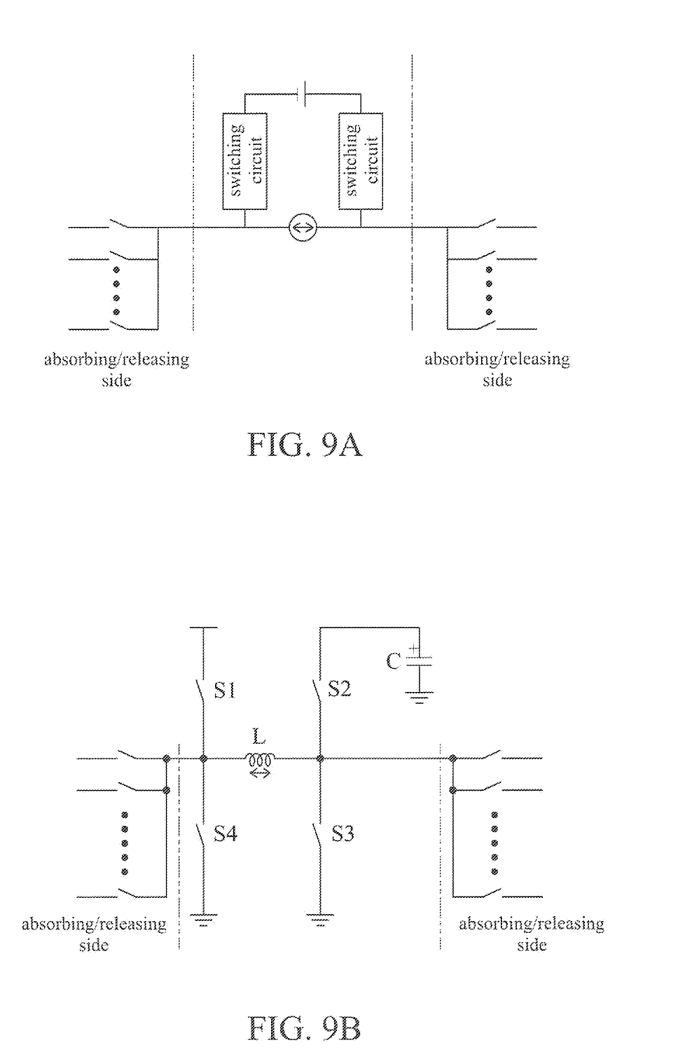

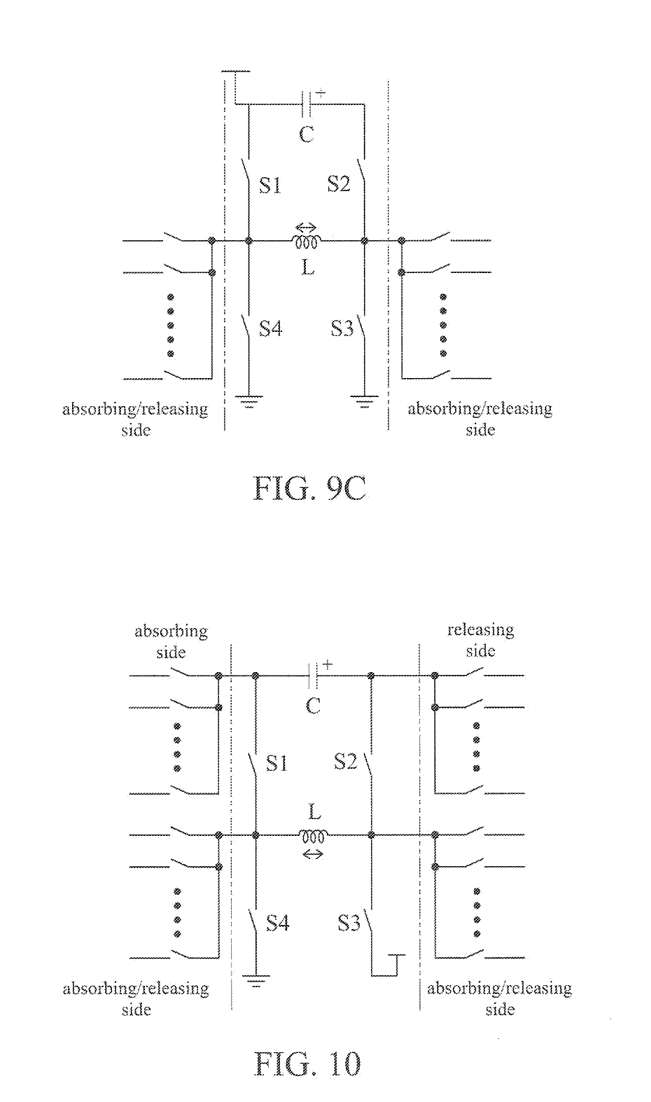

The circuit of FIG. 3B is configured according to FIG. 3A, the circuits of FIG. 4B and FIG. 4C are configured according to FIG. 4A, the circuits of FIGS. 6B, 6C and 6D are configured according to FIG. 6A, the circuits of FIG. 7B and FIG. 7C are configured according to FIG. 7A, the circuits of FIGS. 8B, 8C and 8D are configured according to FIG. 8A, the circuits of FIG. 9B and FIG. 9C are configured according to FIG. 9A, and the circuit of FIG. 10 is configured according to FIG. 1B.

As shown in FIG. 3A, the two switching circuits are connected to the releasing side and the absorbing side respectively, and each of the two switching circuits has two ends respectively connected to a voltage source component and a current source component. Further, as shown in FIG. 3B, the switch S1 is connected to an input power source end, the switch S2 is connected to ground, an inductor L as the current source component is connected to the absorbing side and the releasing side, and a capacitor C as the voltage source component has one end connected to the inductor L and the releasing side and has the other end connected to the ground, wherein the inductor L releases current.

In FIG. 4A, one of the two switching circuits is connected to the absorbing side and the releasing side, one end (output end) of the current source component is connected to the releasing side, one end (input end) of the voltage source component is connected to the absorbing side, and the other of the two switching circuits has two ends respectively connected to the other end of the current source component and the other end of the voltage source component.

The configuration of FIG. 4A may be arranged as the circuit shown in FIG. 4B or FIG. 4C. In the circuit of FIG. 4B, the two ends of the switch S1 are connected to the releasing side and the absorbing side, one end of the capacitor C is connected to the switch S1 and the absorbing side, the other end of the capacitor C is connected to ground; one end (the output end) of the inductor L is connected to the switch S1, the switch S2 and the releasing side, the other end of the inductor L is connected to ground; one end of the switch S2 is connected to the switch S1, the inductor L and the releasing side, and the other end of the switch S2 is connected to the input power source end. The configuration of FIG. 4C differs from the configuration of FIG. 4B in that the capacitor C is connected to the input power source end, rather than to ground.

In the configuration of FIG. 6A, one of the two switching circuits has one end connected to the absorbing side or the releasing side, two ends of the voltage source component are respectively connected to one end of each of the two switching circuits, and the current source component capable of releasing bidirectional current has two ends connected to the other end of each of the two switching circuits. The configuration of FIG. 6A may be arranged as the circuit shown in FIG. 6B, 6C or 6D.

In the circuit of FIG. 6B, the two ends of the switch S1 are respectively connected to one end of the switch S2 and one end of the capacitor C, the other end of the capacitor C and the other end of the switch S2 are connected to ground; and one end of the inductor L is connected to the absorbing side, the switch S1, the switch S2 and the releasing side, and the other end of the inductor L is connected to the input power source end.

The configuration of FIG. 6C differs from the configuration of FIG. 6B in that the capacitor C and the switch S1 are connected with the inductor L in shunt. The configuration of FIG. 6D differs from the configuration of FIG. 6B in the positions of the inductor L and the switch S1.

The configuration of FIG. 7A is similar to the configuration of FIG. 6A except for the position of the absorbing side or the releasing side, i.e. the absorbing side or the releasing side being disposed at the same side as the input end of the voltage source component.

The configuration of FIG. 7A may be further arranged as in FIG. 7B, wherein one end of the switch S1 is connected to the input power source end; the other end of the switch S1 is connected to the releasing side and the absorbing side; one end of the inductor L is connected to the releasing side, the absorbing side and the switch S1; the other end of the inductor L is connected to ground; one end of the switch S2 is connected to one end of the capacitor C in serial; the other end of the switch S2 is connected to the inductor L, the switch S1, the absorbing side and the releasing side; and the other end of the capacitor C is connected to ground.

The configuration of FIG. 7C differs from the configuration of FIG. 7B in the positions of the switch S2 and the capacitor C, i.e. the switch S2 and the capacitor C are connected to the switch S1 in shunt.

In the configuration of FIG. 8A, two ends of each of the two switching circuits are respectively connected to the voltage source component and the unidirectional current source component; one of the two switching circuits is connected to the output end of the voltage source component and the current source component; and the other of the two switching circuits is connected to the input end of the voltage source component and the current source component.

The configuration of FIG. 8A may be further arranged as FIG. 8B, 8C or 8D. In FIG. 8B, the switches S1 and S2 are connected between the input power source end and the ground in serial, the input end of the inductor L is connected to the switch S1 and the switch S2, the output end of the inductor L is connected to the output end of the capacitor C, the switch S3 and the releasing side, the other end of the switch S3 is connected to the ground, and the switch S4 is connected between the input end of the capacitor C and the ground.

The configurations of FIG. 8C and FIG. 8D differ from the configuration of FIG. 8B in the positions of the inductor L, the switch S1 and the switch S2.

In the configuration of FIG. 9A, the ends of the two switching circuits connected to the bidirectional current source component are respectively connected to the absorbing side or the releasing side, and the other ends of the two switching circuits are respectively connected to the output end and the input end of the voltage source component.

The configuration of FIG. 9A may be arranged as the circuits of FIG. 9B and FIG. 9C. In the circuit of FIG. 9B, the switch S1 and switch S4 are connected between the input power source end and the ground in serial; the capacitor C and the switch S2 are connected in serial and connected to ground and inductor L; the switch S3 is connected to ground and the inductor L; and the two ends of the inductor L are connected to the releasing side or the absorbing side, so as to form an H-bridge design, which is not affected by the positions of the releasing side and the absorbing side.

The configuration of FIG. 9C is also an H-bridge design, and differs from the configuration of FIG. 9B in the position of the capacitor C. In the configuration of FIG. 9C, the end of the capacitor C that is not connected to the switch S2 is connected to the input power source end and the switch S1.

The configuration of FIG. 1B may be configured as the circuit of FIG. 10. In FIG. 10, one end of the capacitor C is connected to the absorbing side and the switch S1; the other end of the capacitor C is connected to the switch S2 and the releasing side; one end of the inductor L is connected to the switch S1 and the switch S4; the other end of the inductor L is connected to the switch S2 and the switch S3; two ends of the bidirectional inductor L are optionally connected the absorbing side or the releasing side; the switch S3 is connected to the inductor L and the input power source end; and the switch S4 is connected to the inductor L and ground.

The configurations of FIGS. 3A-3B, 4A-4C, 6A-6C, 7A-7C, 8A-8D, 9A-9C and 10 may be arranged according to FIG. 5B and FIG. 5C for achieving zero voltage/zero current switching, so as to exchange potential energy. Similarly, the absorbing side and the releasing side may be the relatively low voltage side and high voltage side, and the switches may be transistors or diodes.

In comparison with the prior art, the alternate operations of switches in the present invention make the current source component and the voltage source component charge and discharge each other, i.e. exchanging potential energy. Therefore, in addition to zero voltage/zero current switching, the present invention can increase reliability and efficiency, extend the life time, reduce size and achieve energy reuse through fewer components with lower cost.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

1. An energy reuse circuit connected to a plurality of converters, comprising:
an energy absorbing portion;
an energy releasing portion; and
an energy exchange portion connected to the energy absorbing portion and the energy releasing portion, wherein the energy exchange portion is configured to allow the energy absorbing portion and the energy releasing portion to exchange potential energy in sequence, thereby completing energy reuse.

2. The energy reuse circuit of claim 1, wherein the energy exchange portion is a switching circuit, and the energy absorbing portion and the energy releasing portion are current source components or voltage source components, in which two ends of the switching circuit are respectively connected to the current source components and the voltage source components, and the current source components or the voltage source components are connected to releasing sides or absorbing sides of the converters.

3. The energy reuse circuit of claim 2, wherein the switching circuit includes a switch, an open circuit or a short circuit.

4. The energy reuse circuit of claim 3, wherein the switch is transistor, diode, thyristor or relay.

5. The energy reuse circuit of claim 2, wherein the current source components are unidirectional or bidirectional current source components.

6. The energy reuse circuit of claim 2, wherein the current source components are inductors.

7. The energy reuse circuit of claim 2, wherein the voltage source components are polarized voltage source components.

8. The energy reuse circuit of claim 2, wherein the voltage source components are capacitors.
